(19) United States
(12) Patent Application Publication
(10) Pub. No.: US 2018/0184516 A1
(43) Pub. Date: Jun. 28, 2018

(54) PRINTED WIRING BOARD

(71) Applicant: NEC Corporation, Minato-ku, Tokyo (JP)

(72) Inventors: Kazuhiro KASHIWAKURA, Tokyo (JP); Ayako UEMURA, Tokyo (JP)

(73) Assignee: NEC Corporation, Minato-ku, Tokyo (JP)

(21) Appl. No.: 15/738,218

(22) PCT Filed: Jul. 4, 2016
(86) PCT No.: PCT/JP2016/003169

§ 371 Date: Dec. 20, 2017

(30) Foreign Application Priority Data
Jul. 8, 2015 (JP) 2015-137092

(51) Int. Cl. H05K 1/02; H05K 1/11; H05K 1/14; H05K 1/18

(52) U.S. Cl. CPC H05K 1/0224; H05K 1/115; H05K 1/141; H05K 2201/10189; H05K 2201/09609; H05K 2201/1003; H05K 2201/10356; H05K 1/185

(57) ABSTRACT

An objective of the present invention is to provide a printed board capable of suppressing EMI emissions from an electric cable. To accomplish the objective, the present invention is a printed board including a signal wiring to which an electric cable is connected, the printed board including: ground layers above and below the signal wiring put on upper and lower sides of the signal wiring to which the electric cable is connected; and a plurality of through holes connecting the ground layers above and below the signal wiring, wherein the plurality of the through holes are disposed at and near the signal wiring and are spaced apart at intervals according to a wavelength corresponding to a maximum frequency of electromagnetic waves to be suppressed.

### TECHNICAL FIELD

The present invention relates to a printed board, which suppresses electro-magnetic interference (EMI) emissions, particularly to a printed board, which suppresses EMI emissions from an electric cable.

### BACKGROUND ART

Upon an electric signal cable and a power feeding cable are connected to a printed board, the printed board is remarkably degraded even if perfect measures for EMI in information communication equipment are taken. This is known empirically, and taking the measures to the printed board has been repeated at each time when degraded.

In recent years, getting larger capacities of the information communication equipment leads increases of speed of signals or sizes of equipment and causes higher frequencies of power supply noise or multi-purposing of resonance modes in the inside of the equipment, thus having become hard to conform to EMI regulations such as Voluntary Control Council for Interference by Information Technology Equipment (VCCI). In particular, since the electric cable is often used to connect between the equipment in the information communication equipment, the phenomenon that electromagnetic waves generated in the printed board are propagated to the electric cable and are emitted (EMI-emitted) as the electromagnetic waves to the outside of the printed board has not been suppressed completely.

As described below, while following proposals have been made for EMI reduction techniques, EMI emissions have not been solved.

PTL1 (Japanese Unexamined Patent Application Publication No. 2013-254759) discloses a technique that a square ring-shaped GND wiring is arranged along the periphery of an LSI circuit board and is connected to a GND layer in the board by a plurality of GND via holes (paragraphs [0014] to [0019], FIG. 1 etc. in PTL1). Although there are some effects for suppressing EMI by arranging the GND via holes, the effects are insufficient to block electromagnetic waves in the board, because a great gap is presence due to the GND wiring shaped in the square ring, which the electromagnetic waves are leaked from the gap. Further, techniques for blocking the EMI emissions from the electric cable caused by transferring, through the electric cable, the electromagnetic waves generated in the printed board are not disclosed.

In addition, PTL2 (Japanese Unexamined Patent Application Publication No. H10-270862) and PTL3 (Japanese Unexamined Patent Application Publication No. 2001-53449) disclose techniques that impedance with an external power supply is increased by allowing power feeding wirings of large scale integrations (LSIs) to have inductors, thus suppressing propagation of the power supply noise to the outside (paragraphs [0023], [0025], FIGS. 2, 3 in PTL2, paragraphs [0036] to [0037], FIGS. 2, 3 in PTL3). However, the power supply noise is generated by transmitting the electromagnetic waves through between the power supply and a GND as if a transmission path, thus propagating the electromagnetic waves to its circumference. Therefore, it is hard to fundamentally suppress EMI. Further, similar to PTL 1, PTL 2 does not disclose the blocking of the electromagnetic waves from the printed board to the electric cable.

In PTL 4 (WO 2014/080610), a technique for analyzing the electromagnetic waves propagating from a printed board to an electric cable is disclosed. However, PTL 4 does not disclose techniques for suppressing the emissions.

In PTL 5 (Japanese Unexamined Patent Application Publication No. 2000-216509), ground layers are formed above and below a wiring conductor for signals, above and below each side thereof so as to prevent the electromagnetic waves generated from the wiring conductor for signals formed on an insulating base from leaking to the outside, and at least double rows of penetrating conductors (through holes) are formed such that the wiring conductor for signals is put between the at least double rows of penetrating conductors from the each side of the wiring conductor (in FIG. 1 of PTL 5, the through holes are formed in the entire board). Further, PTL 5 describes that an interval between a first row and a second row of the penetrating conductors is set as the interval equal to or below a quarter of a wavelength λ of a high-frequency signal to be propagated to the wiring conductor for signals (in PTL 5, [0017] to [0018], [0023], FIGS. 1, 3, 4).

However, PTL 5 has an objective for decreasing the leakage of the electromagnetic waves from the insulating base to the outside and does not disclose techniques that block the electromagnetic waves from the insulating base to the electric cable.

In addition, in PTL 6 (Japanese Unexamined Patent Application Publication No. H11-220263), ground layers are put above and below both of power supply layers and signal layers, the ground layers above and below the both of the power supply layers and signal layers are connected by a plurality of through holes ([0008] to [0009], FIGS. 1, 2).

However, PTL 6 has an objective for decreasing the leakage of the electromagnetic waves from the printed wiring board to the outside and does not disclose techniques that block the electromagnetic waves from the insulating base to the electric cable.

### CITATION LIST

### Patent Literature

[PTL 1] Japanese Unexamined Patent Application Publication No. 2013-254759
[PTL 2] Japanese Unexamined Patent Application Publication No. H10-270862
[PTL 3] Japanese Unexamined Patent Application Publication No. 2001-53449
[PTL 4] WO 2014/080610
[PTL 5] Japanese Unexamined Patent Application Publication No. 2000-216509
[PTL 6] Japanese Unexamined Patent Application Publication No. H11-220263

[PTL 7] Japanese Unexamined Patent Application Publication No. H09-266370
[PTL 8] Japanese Unexamined Patent Application Publication No. H07-321429

### SUMMARY OF THE INVENTION

### Technical Problem

The foregoing PTLs 1 to 8 all have not solved problems for the EMI emissions from the electric cable caused by transmitting, through the electric cable, the electromagnetic waves generated in the printed board.

An objective of the present invention is to solve the problems described above and provide a printed board capable of suppressing EMI emissions from an electric cable.

### Solution to Problem

The present invention is a printed board including a signal wiring to which an electric cable is connected, the printed board including: ground layers above and below the signal wiring put on upper and lower sides of the signal wiring to which the electric cable is connected; and a plurality of through holes connecting the ground layers above and below the signal wiring, wherein the plurality of the through holes are disposed at and near the signal wiring and are spaced apart at intervals according to a wavelength corresponding to a maximum frequency of electromagnetic waves to be suppressed.

### Advantageous Effects of the Invention

The present invention can suppress the EMI emissions from the electric cable.

### BRIEF DESCRIPTION OF THE DRAWINGS

FIG. 1 is a plan view and a cross-sectional view illustrating a printed board of a first example embodiment of the present invention;

FIG. 2 is a diagram illustrating an analytical model for electromagnetic field analysis in the first example embodiment;

FIG. 3 is a plan view illustrating a differential signal wiring for cable transmission 61 of the first example embodiment;

FIG. 4 is a diagram illustrating a mechanism of EMI emissions to pass the electromagnetic waves into an electric cable from the printed board;

FIG. 5 is a diagram illustrating an analysis result of electric field intensities in the inside and outside of the printed board when the GND through holes are not formed;

FIG. 6 is a result of analyzing a relationship between frequencies and the electric field intensities measured by a probe, which is positioned at an observation point in the outside of the board, when the GND through holes are not formed in FIG. 4;

FIG. 7 is a diagram illustrating an analysis result of the electric field intensities in the inside and outside of the printed board when the only single layer (single row) of the GND through holes is formed along the periphery of the board;

FIG. 8 is a diagram where the configuration of FIG. 7 is analyzed similar to FIG. 5;

FIG. 9 is a diagram illustrating an analysis result of the electric field intensities in the inside and outside of the printed board when the GND through holes are formed both along the periphery of the printed board and around the signal wiring for the cable;

FIG. 10 is a diagram where the configuration of FIG. 9 is analyzed similar to FIG. 5;

FIG. 11 is a diagram for analyzing a relationship between frequencies and the electric field intensities in no GND through holes, a single row, double rows, and triple rows of the GND through holes; and

FIG. 12 is a plan view illustrating a second example embodiment of the present invention.

### DESCRIPTION OF EMBODIMENT

### First Example Embodiment

(Description of Configurations)

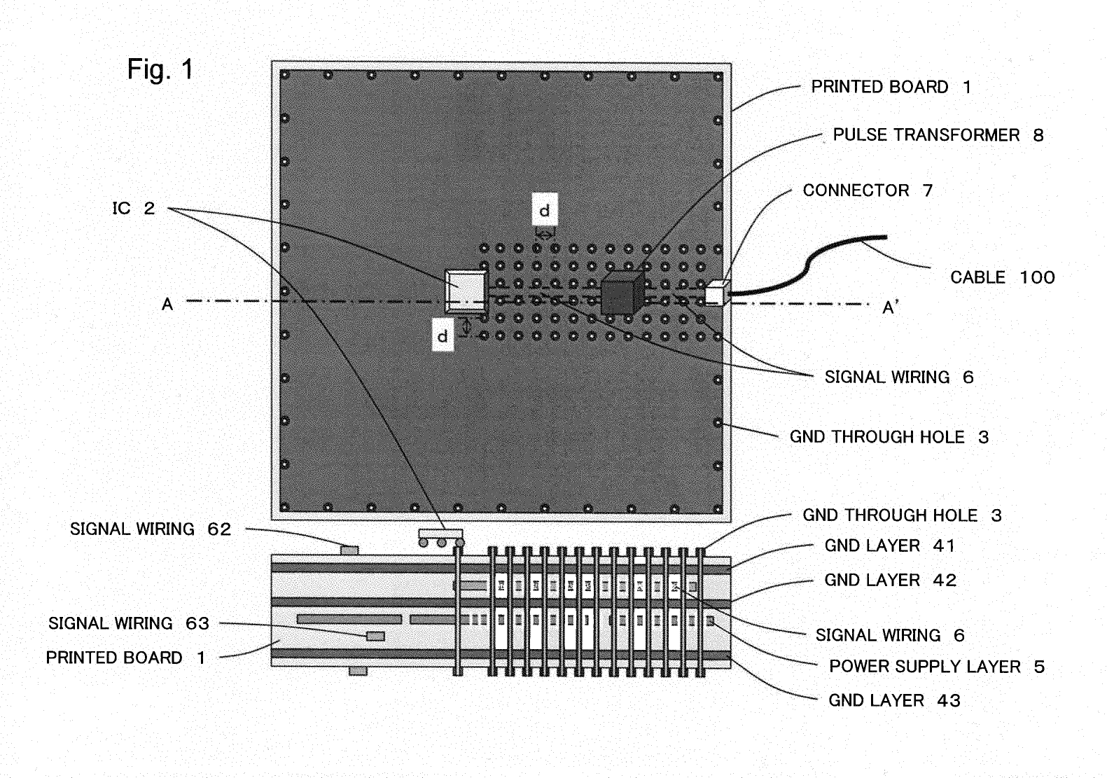

FIG. 1 is the plan view and the cross-sectional view illustrating the first example embodiment of the present invention. The cross-sectional view illustrates a cross section taken along a dashed-dotted line A-A′ in the plan view. The cross-sectional view illustrates a signal wiring 6 and power supply layers 5 passing between GND through holes 3. The signal wiring 6 connected to signal terminals of an IC 2 passes in the board and is connected to a pulse transformer 8, thus being connected to an electric cable 100. Further, signal wirings 62, 63 that are not connected to the electric cable 100 are also formed on and in the board.

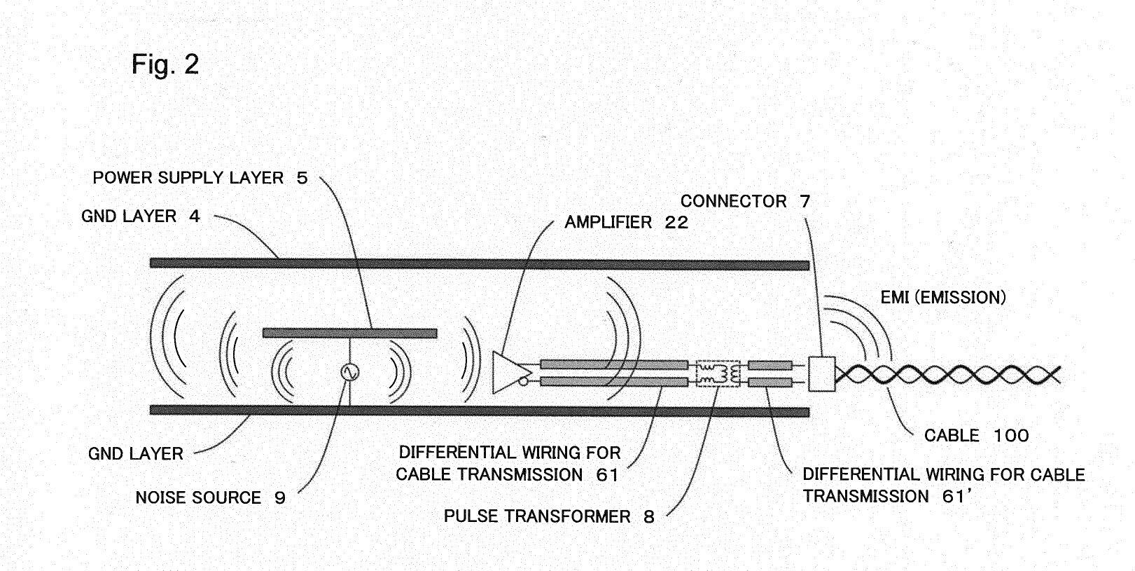

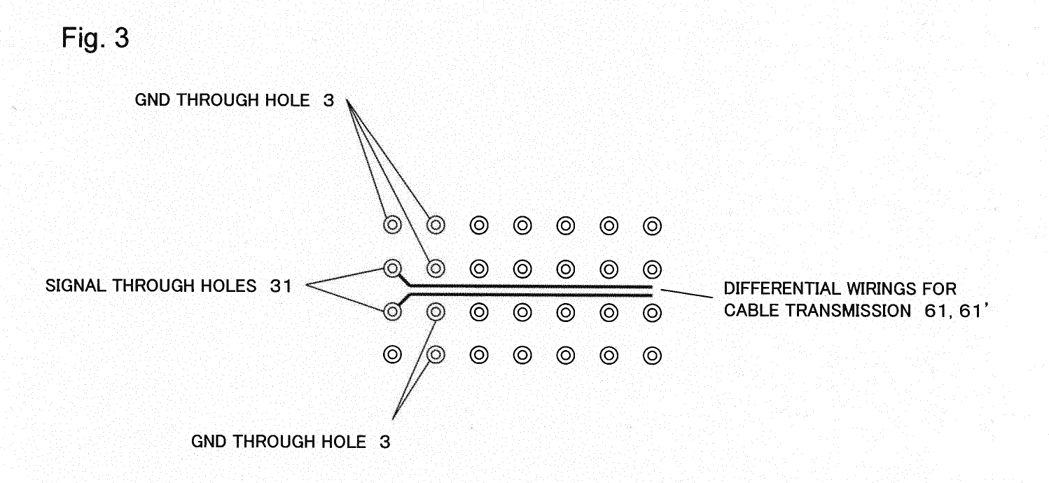

The printed board 1 is a multilayer printed board in which, by putting insulating layers therebetween, the power supply layers 5 and the signal wiring 6 connected to the electric cable are formed. Specifically, in the present example embodiment, the signal wiring 6 is differential wirings for cable transmission 61, 61′ illustrated in FIG. 2. The differential wiring for cable transmission 61 connects between the IC 2 and the pulse transformer 8; the differential wiring for cable transmission 61′ connects between the pulse transformer 8 and the connector 7. FIG. 3 is the plan view illustrating the wiring state of the differential signal wirings for cable transmission 61, 61′. The differential signal wirings for cable transmission 61, 61′ are connected to signal through holes 31 that are connected to the IC 2, and are wired, between the GND through holes 3 arranged in a grid pattern, parallel and close to each other on the same layer. Double rows of the GND through holes 3 for controlling impedance are disposed on each side of the differential signal wirings for cable transmission 61, 61′.

Further, on directly under a component surface that is one surface of the printed board 1 in FIG. 1 and directly over a solder surface that is the opposite surface of the printed board 1, GND layers 41, 43 are formed, respectively, and also in the middle of the board 1 a power supply layer 42 is formed. The GND layers 41, 42, 43 are GND solid plane grounds, i.e., grounds that are formed in the entire area of the board. Note that in FIG. 1, illustrations of solders are omitted.

The IC 2 is implemented on the printed board 1 to drive the electric cable such as an ether connector and is connected to the electric cable (copper cable) 100 through a connector 7 such as RJ45, by the signal wiring 6. The IC 2 is generally referred to as a physical layer (PHY) chip.

The pulse transformer 8 is generally implemented between the PHY and the RJ45 connector, and noise suppressions etc. are performed by cutting DC or common mode choke-coil (CMC).

The upper and lower layers of the signal wiring 6 are GND layers (ground layers) 41, 42, respectively, and the GND through holes 3 connecting at least the two GND layers are arranged around the board. In the present example embodiment, the GND through holes 3 connect all of the GND layers 41, 42, 43. Around the wiring connecting from the IC 21 (PHY) to the connector, the GND through holes 3 are arranged at intervals d (conditions for d will be described later) in the grid pattern.

(Description of Operations)

FIG. 2 is the diagram illustrating the analytical model for electromagnetic field analysis in the present example embodiment. The mechanism of EMI emissions to pass the electromagnetic waves into the electric cable 100 from the printed board 1 will be described using FIG. 2. A board configuration applied in the present example embodiment is the power supply layer 5 put between the GND layers. By operations of the IC 21 the power supply current is changed, and a potential between the power supply layer 5 and the GND layers 4 subsequently changes, i.e., an electric field changes, thus generating the electromagnetic waves. The change of the power supply current is simulated by a noise source 9. An amplifier 22 corresponds to the IC 2 of FIG. 1. The electromagnetic waves generated from a noise source 9 are propagated to all directions through between the power supply layers 5 and GND layers 4 as if a transmission path. The propagated electromagnetic waves are further propagated until edges of the board through, e.g., between the GND layer 4 and the GND layer 4 or between the other power supply layer and GND layer even in range where there are no power supply layer 5, or between the power supply layer and the power supply layer, as if the transmission path. The electromagnetic waves propagating from the edges of the board to the outside of the board are the EMI emissions.

It is assumed now that the differential wiring for cable transmission 61 is arranged between the GND layer 4 and GND layer 4. The electromagnetic waves generated from the noise source 9 are excited into the differential wiring for cable transmission 61. Thus, the electromagnetic waves become EMI emissions by propagating from the signal wirings 6 to the outside of the printed board 1 through the connector 7 and the electric cable 100. When the pulse transformer or the CMC is implemented, the electromagnetic waves also affect the pulse transformer itself. Therefore, the remarkable effects cannot be expected by the pulse transformer or the CMC.

To prevent the EMI emissions from the electric cable, in the present example embodiment, the GND through holes 3 are arranged in the grid pattern, around the differential wiring for cable transmission 61. It is desirable that the grid interval d is equal to or below a quarter of a wavelength λ of a maximum frequency fₘₐₓ to be suppressed. In other words, relative dielectric constant of the printed board is set as εᵣ, and light velocity as C₀, thus being capable of leading the following condition:

d≤λ/4=C₀/(4·fₘₐₓ·√εᵣ) (math 1)

Note that the electromagnetic wave having a longer wavelength than λ/2 cannot pass through the grid of the GND through holes 3. If the GND through holes 3 are perfect conductors, the interval thereof may be defined at λ/2. However, if the interval is defined at λ/2, the electromagnetic wave can pass through the grid of the GND through holes 3, because actual through holes are not perfect conductors. Therefore, the math 1 has been defined by setting the grid interval as λ/4. Taking the relative dielectric constant of the printed board at 4 and the maximum frequency fₘₐₓ to be suppressed at 1 GHz yields:

d≤3×10⁸/(4×1×10⁹×√4)=37.5 mm

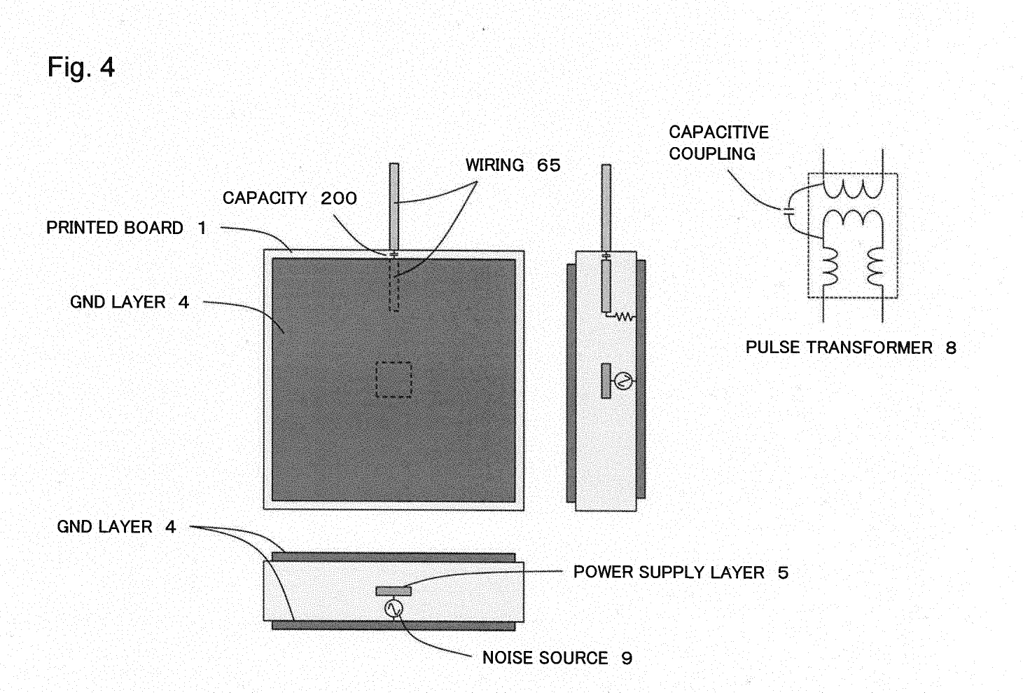

For verification of these effects, a model like FIG. 4 is made, and the effects are verified by the electromagnetic field analysis. In the analytical model, a power supply layer and a signal wiring are arranged, which are put between two of the GND layers 4. In FIG. 4, the cable is simulated by a wiring 65. Further, the wiring 65 is combined to the signal wiring 6 in the printed board 1 by a capacity 200. This simulates a capacitive coupling of a primary side (IC side) and a secondary side (electric cable side) of the pulse transformer 8. On the right side of FIG. 4, a model corresponding to the pulse transformer 8 is illustrated. The presence or absence of the GND through holes is added as a condition to the analytical model illustrated in FIG. 4, and electric field distributions and neighborhood electric field intensities are calculated by the electromagnetic field analysis.

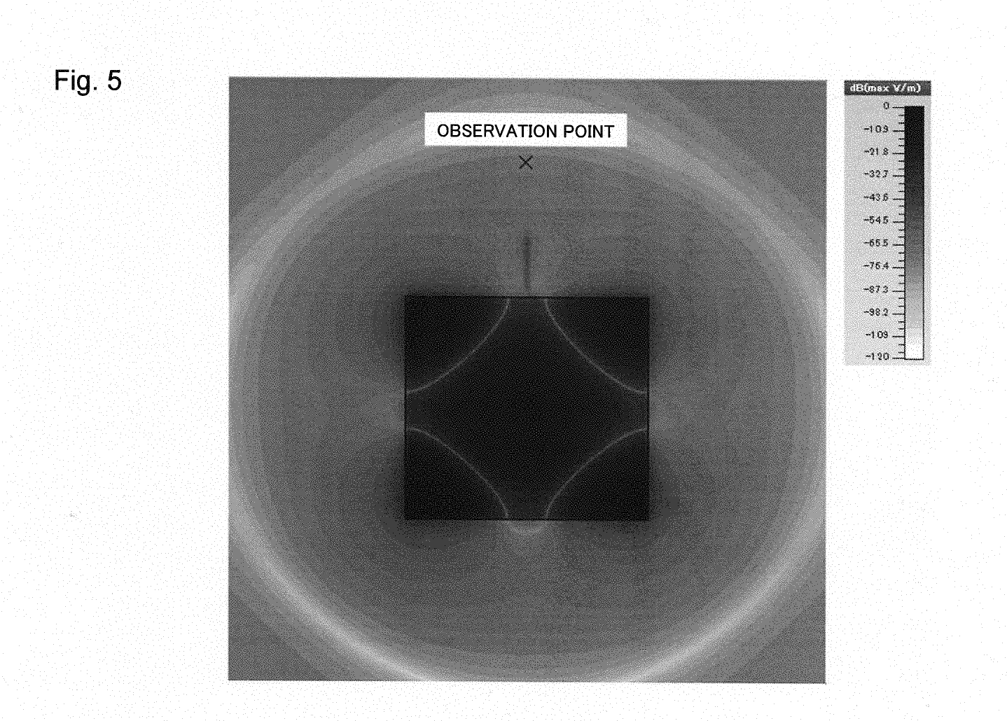

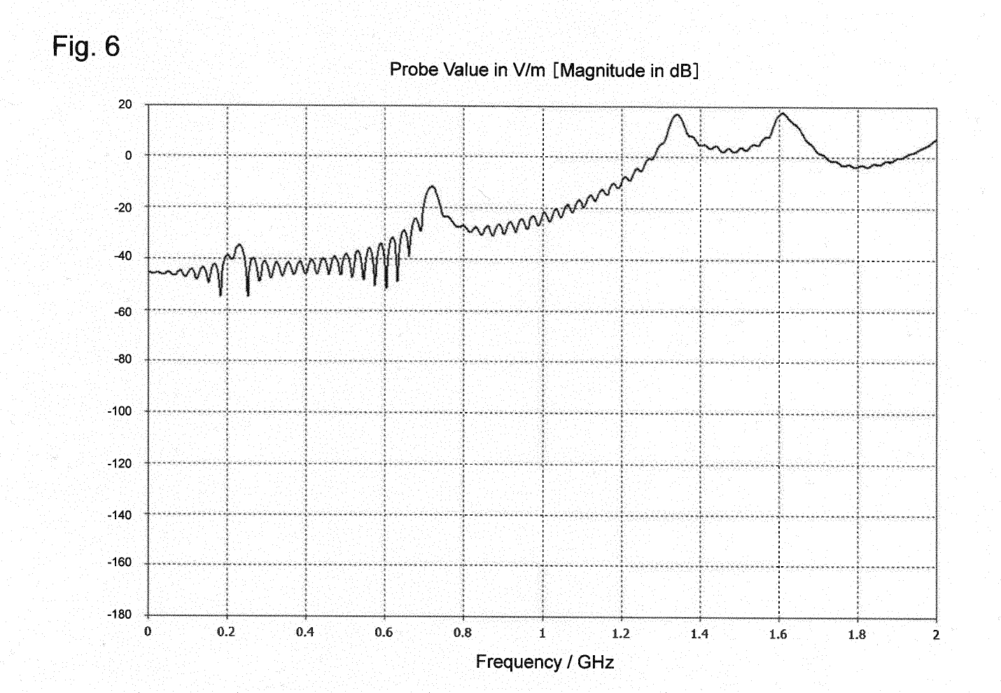

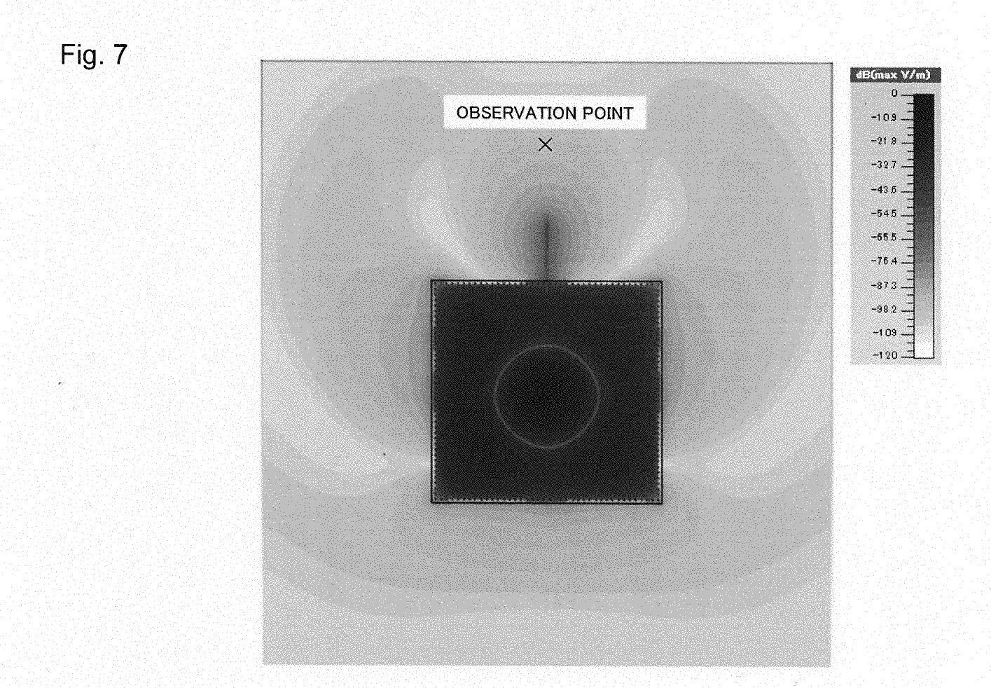

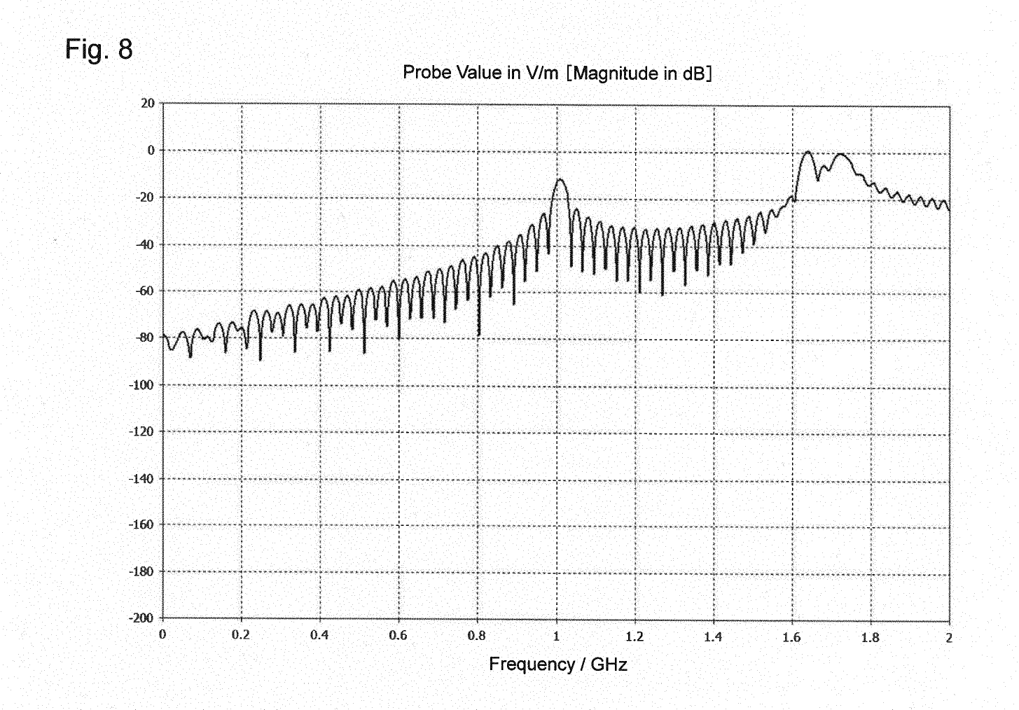

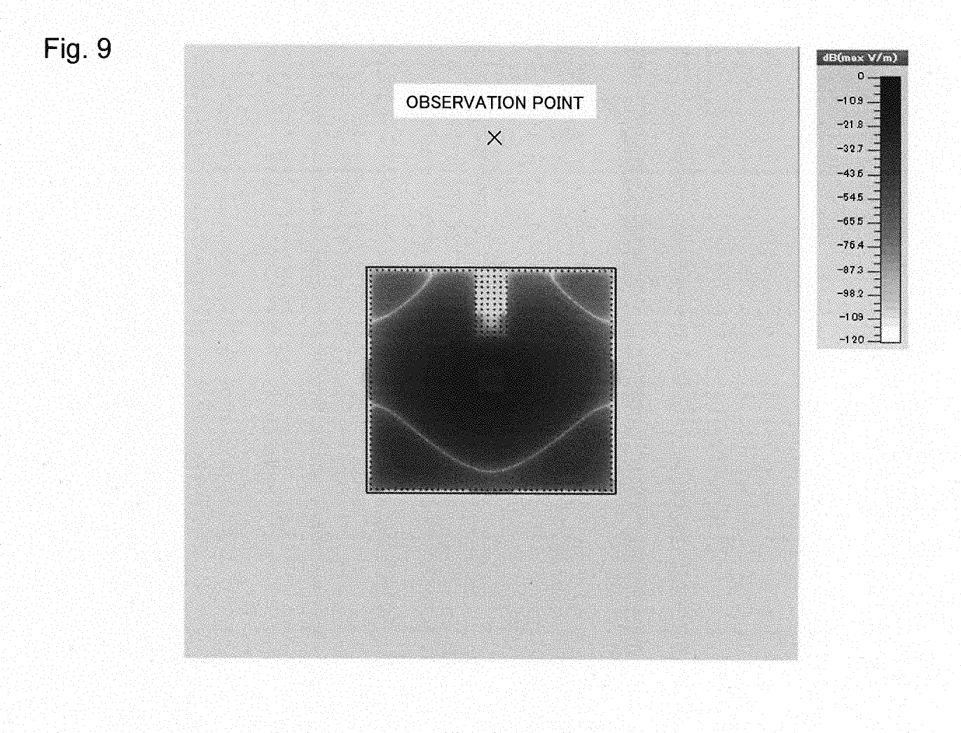

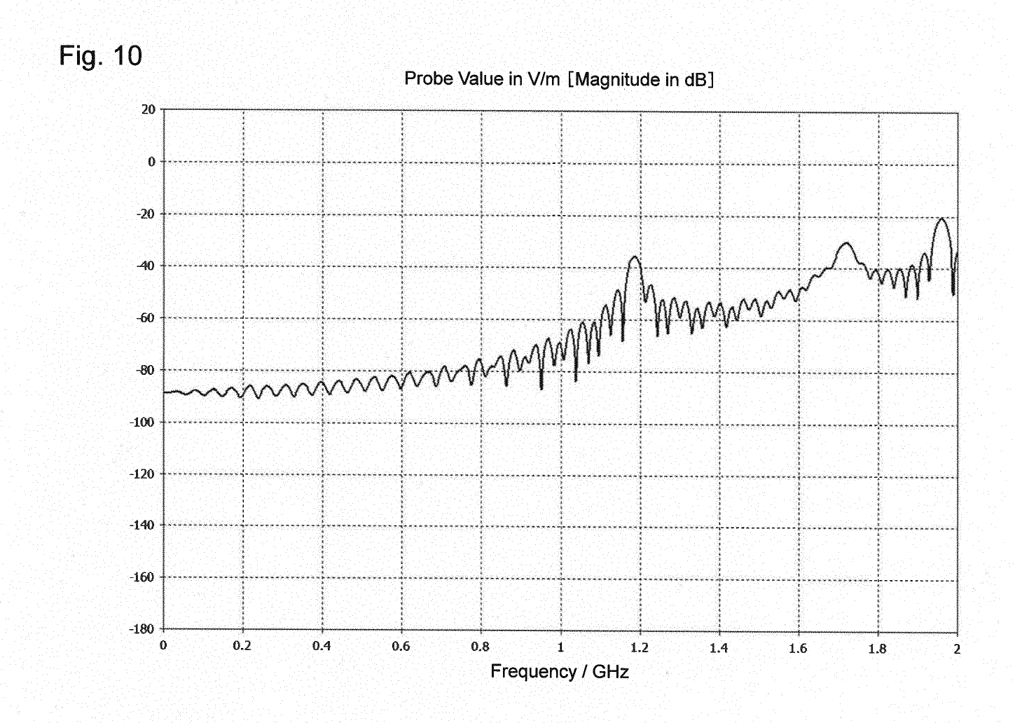

The analysis results are illustrated in the FIG. 5 to FIG. 10. FIG. 5 and FIG. 6 are results when there are no GND through hole in the printed board. FIG. 7 and FIG. 8 are results when the GND through holes are arranged only around the printed board. FIG. 9 and FIG. 10 are results when the GND through holes are arranged both around the printed board and around the signal wiring for the cable. FIGS. 6, 8, and 10 are the diagrams illustrating the relationships between the frequencies and the electric field intensities measured by the probe, which is positioned at the observation point outside the board (a sign x in the figure), concerning FIGS. 5, 7, and 9, respectively.

Although the actual power supply layer (power supply wiring) typically has an elongate shape, the analysis has been made assuming herein that the power supply layer is a square for simplifying the analysis. Further, a scale in upper right side of FIG. 5, 7, or 9 directs from zero to negative numeric values. As the numeric values direct toward negative, the electric field intensities are lower; as the numeric values close to zero, the electric field intensities are higher. The unit thereof is dB·V/m, and the scales in FIGS. 5, 7, and 9 are presented using the unit of “max dB·V/m”, because the relative values in which the injected energy is assumed as a maximum value (zero dB or one) are plotted in FIGS. 5, 7, and 9.

FIG. 5 is the analysis result when the GND through holes 3 are not formed. The shape of the electric cable 100 is clearly observed, and it is obvious that the electric field intensities around the electric cable 100 are higher than those of other positions in the outside the board. In addition, with reference to FIG. 6, upon the frequency being equal to or more than 1 GHz, the electric field intensities reach up to about 20 dB·V/m (in 1.3 to 1.6 GHz) over −20 dB·V/m.

FIG. 7 is the analysis result when only single circuit (single row) of the GND through holes 3 is formed along the periphery of the printed board, and some EMI emissions to the outside of the board can be suppressed. However, the electric field intensities around the electric cable 100 are higher than those of other spaces, it is found that the emissions from the electric cable 100 cannot be suppressed. With reference to FIG. 8, the electric field intensities reach up to zero dB·V/m (in about 1.7 GHz), and it is not sufficiently to suppress the electromagnetic waves.

FIG. 9 is a result when the GND through holes are formed both around the printed board and around the signal wiring for the cable, and the emissions from the electric cable 100 are indistinguishable from other spaces in the outside of the board. With reference to FIG. 10, the electric field intensities are declined as −20 dB·V/m at most (in about 2 GHz), and it is found that the electromagnetic waves can be suppressed. In other words, it is found that the GND through holes around the signal wiring for the cable suppress the emissions from the electric cable 100.

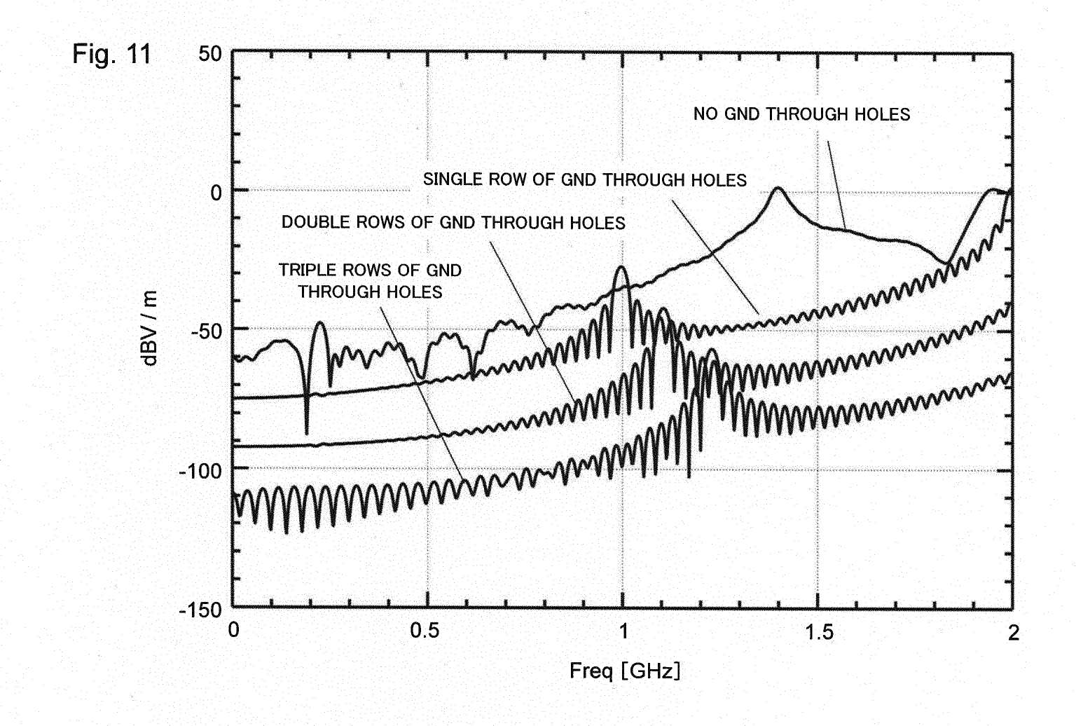

In FIGS. 5 to 10, triple rows of the GND through holes 3 are formed on each side of the signal wiring 6 along its running direction. However, the GND through holes 3 may be formed in at least double rows on the each sides of the signal wiring 6. FIG. 11 is results of analyzing the relationship between frequencies and the electric field intensities in no GND through holes, a single row, double rows, and triple rows of the GND through holes. The result of the no GND through holes corresponds to FIG. 6, the result of the single row thereof to FIG. 8, and the result of the triple rows thereof to FIG. 10. A result of the double rows of the GND through holes is a data that the electric field intensities are declined as −40 dB·V/m at most (in about 2 GHz), and it is found that the effect of the double rows thereof is sufficient for suppressing of the emissions. Note that in comparison of FIG. 11 to FIGS. 6, 8 and 10, absolute values of the electric field intensities of the no GND through holes, the single row, and the triple rows thereof are slightly different from those of the FIGS. 6, 8, and 10. This is caused by differences in the conditions of the board to be measured, or the like. However, the result of the double rows of the GND through holes involves same condition as those of the board to be measured, the data is sufficient for being capable of utilizing for the comparison.

Note that in FIGS. 5 to 10, the single circuit of the GND through holes is formed as along the periphery of the printed board, and this has reasons as follows: the EMI emissions are caused from the power supply layers etc. in the board and from the electric cable; if first the former is not removed, it cannot be determined whether or not the present example embodiment has the effect for suppressing the latter. Therefore, the analysis has been made, using the model in which the GND through holes are formed along the periphery of the board.

(Descriptions of Effects)

When the GND through holes 3 are arranged around the signal wiring 6 that is connected to the electric cable, the electromagnetic waves from the printed board 1 are blocked against the electric cable 100 completely. This result shows that the EMI emissions from the electric cable 100 can be suppressed sufficiently. Using the printed board 1 of the present example embodiment facilitates designs and developments of products.

Note that the printed board 1 of FIG. 1 also includes the power supply layers 5. The EMI emissions from the power supply layers 5 are possible, and the GND layer 42 is disposed above the power supply layers 5. Therefore, the electromagnetic waves from the power supply layers 5 are not propagated to the signal wiring 6.

Note that in the present example embodiment, although the differential wiring for cable transmission is used as the signal wiring 6, not the differential wiring but a single signal wiring may be applied.

### Second Example Embodiment

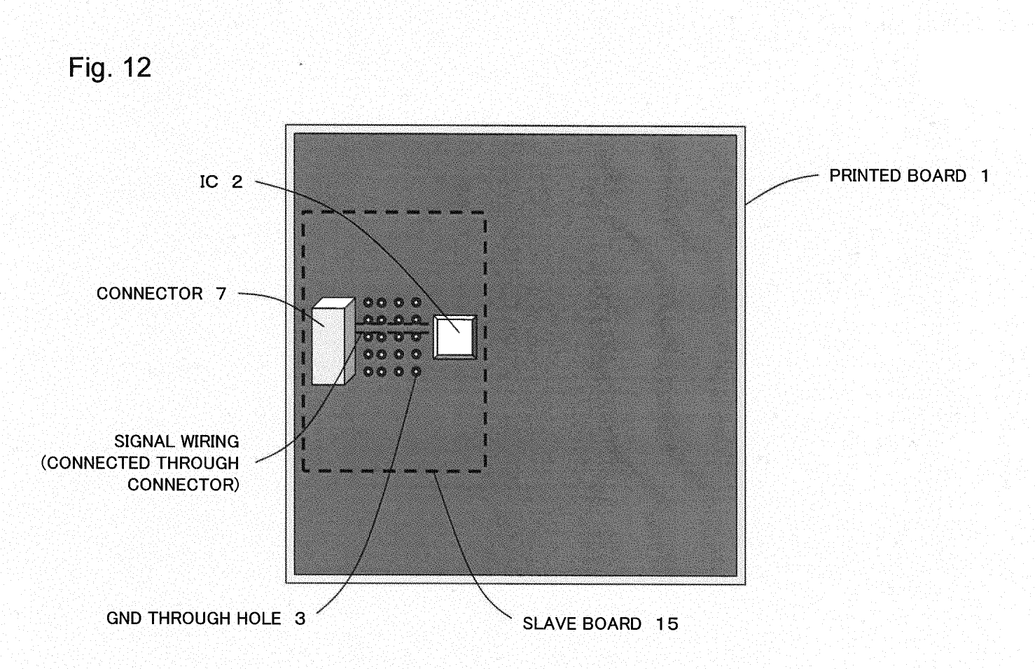

FIG. 12 illustrates the second example embodiment of the present invention. This is composed of two-storied board so as to include a slave board 15 (such as a daughter card or a sub card) in the equipment. A portion illustrated with a broken line in FIG. 12 is the slave board 15, and a connector 7, a signal wiring 61, and an IC 2, which are connected to a cable (not illustrated), are mounted on the slave board 15. The present example embodiment is in the case that the wiring which connects the IC 2 and the connector 7 on the slave board 15 is formed, and in this case, the present invention can be applied thereto.

### Third Example Embodiment

In the foregoing first and second example embodiments, although the GND through holes 3 are arranged parallel to the signal wiring 6, the GND through holes may be arranged in a zigzag, i.e., in staggered to the running direction of the signal wiring 6. In such arrangement, the interval between the through holes can be narrower. Thus, the area of ranges where the through holes are formed can be smaller.

The illustrations of the present invention have been made using the foregoing example embodiments by way of exemplary examples. However, the present invention is not limited to the foregoing example embodiments. Namely, a variety of aspects that may be appreciated by those skilled in the art are applicable to the present invention, within the scope of the invention.

The present application claims priority based on Japanese patent application No. 2015-137092 filed on Jul. 8, 2015, the entire disclosures of which are incorporated herein.

### REFERENCE SIGNS LIST

1 printed board

2 IC

3 GND through hole

4, 41, 42, 43 GND layer

5 power supply layer

6 signal wiring

62, 63 signal wiring

61, 61′ differential wiring for cable transmission

65 wiring

7 connector

8 pulse transformer

9 noise source

15 slave board

22 amplifier

100 electric cable

200 capacity

What is claimed is:

1. A printed board comprising a signal wiring to which an electric cable is connected, the printed board comprising:
ground layers above and below the signal wiring put on upper and lower sides of the signal wiring to which the electric cable is connected; and
a plurality of through holes connecting the ground layers above and below the signal wiring,
wherein the plurality of the through holes are disposed on each side of the signal wiring and are spaced apart at intervals according to a wavelength corresponding to a maximum frequency of electromagnetic waves to be suppressed.

2. The printed board according to claim 1,
wherein double rows of the plurality of the through holes are disposed on the each sides of the signal wiring.

3. The printed board according to claim 1, comprising:
a plurality of ground layers,
wherein through holes connecting between the plurality of the ground layers are disposed around the printed board.

4. The printed board according to claim 1,
wherein the intervals between the plurality of the through holes are equal to or below a quarter of a wavelength corresponding to the maximum frequency of the electromagnetic waves to be suppressed.

5. The printed board according to claim 1,
wherein the ground layers are layers of plane grounds.

6. The printed board according to claim 1,
wherein the signal wiring to which the electric cable is connected is connected to a connector while putting a transformer therebetween, and is connected by the connector to the electric cable.

7. The printed board according to claim 1,
wherein the through holes are arranged parallel or with an inclination to the signal wiring.

8. The printed board according to claim 1, comprising:
a slave board disposed on the printed board,
wherein the signal wiring to which the electric cable is connected is disposed on the slave board.
